(19) United States
(12) Patent Application Publication
(10) Pub. No.: US 2005/0225343 A1
(43) Pub. Date: Oct. 13, 2005

(54) Device and method of testing an electronic component

(75) Inventor: Erik Harold Groot, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: Koninklijke Philips Electronics N.V., NL-5621 BA Eindhoven (NL)

(21) Appl. No.: 10/516,146

(22) PCT Filed: Jun. 3, 2003
(86) PCT No.: PCT/IB03/02091

§ 371 Date: Nov. 30, 2004

(30) Foreign Application Priority Data
Jun. 3, 2002 (EP) 02077167.1

(51) Int. Cl. G01R 31/02

(52) U.S. Cl. 324/755

(57) ABSTRACT

Device (1) and method for testing an electronic component (21), which device comprises a testing mechanism (2) and a mounting mechanism (3) comprising a component contact surface (14) on a side remote from the testing mechanism (2), wherein the component contact surface is provided with a vacuum chamber connected to a vacuum means (19). The mounting mechanism is provided with a heating element (24), by means of which the component contact surface can be heated.

The invention relates to a device for testing an electronic component, which device is provided with a testing mechanism and a fastening mechanism which comprises a component contact surface at a side facing away from the testing mechanism.

The invention further relates to a method of testing an electronic component by means of such a device.

Such a device and such a method are known per se from U.S. Pat. No. 6,054,869. In the device described therein, an electronic component to be tested is positioned on a component contact surface of a fastening mechanism, whereupon the fastening mechanism is displaced to a testing mechanism by a displacement device. Contact elements present on the electronic component are thus brought into contact with the testing mechanism. After testing of the component, the fastening mechanism is displaced in a direction away from the testing mechanism, whereupon the electronic component is removed from the device.

It is a disadvantage of the known device and method that the electronic component lies loosely on the fastening mechanism, so that the electronic component can be shifted, for example during displacement of the fastening mechanism to the testing mechanism, with the result that no or an incorrect contact is achieved between the electronic component and the testing mechanism. To avoid this risk, it is possible to press the electronic component mechanically against the component contact surface from a side facing away from the testing mechanism. This has the disadvantage, however, that there is a risk of the surface of the electronic component facing away from the testing mechanism becoming damaged.

The invention has for its object to provide a device with which the above disadvantages are avoided, while a secure contact between the electronic component and the fastening mechanism is guaranteed during testing.

This object is achieved in the device according to the invention in that the component contact surface is provided with a vacuum chamber connected to a vacuum means.

The vacuum means is capable of generating a vacuum in the vacuum chamber, so that the electronic component situated on the component contact surface will be securely pulled against the component contact surface. A strong contact between the electronic component and the fastening mechanism will be obtained thereby. Since no mechanical forces are exerted on the surface of the electronic component facing away from the testing mechanism, the risk of damage of this surface is avoided.

The component may be gripped, for example, at lateral edges so as to be positioned on the fastening mechanism. It is alternatively possible, however, to grip the electronic component nevertheless from the upper side, for example by vacuum means. The pressing of the electronic component against the fastening mechanism, however, takes place by means of the vacuum to be generated in the vacuum chamber.

An embodiment of the device according to the invention is characterized in that the fastening mechanism is provided with a heating element by means of which the component contact surface can be heated.

The heating element renders it possible to bring the fastening mechanism to a temperature desired for testing.

A further embodiment of the device according to the invention is characterized in that the component contact surface is provided with at least one heat transmission element.

The heat transmission element situated in the component contact surface renders it possible to bring the component to a temperature desired for testing. In addition, the temperature may be kept constant, for example by means of a temperature sensor.

A yet further embodiment of the device according to the invention is characterized in that the vacuum chamber comprises channels which are provided in the component contact surface and which are in communication with one another, while the heat transmission element comprises portions of the component contact surface situated between the channels.

The component contact surface is suitable both for pulling the electronic component against the component contact surface by suction and for heating the electronic component situated thereon thanks to the channels and the portions of the component contact surface situated between the channels.

Another further embodiment of the device according to the invention is characterized in that a sealing ring bounding the vacuum chamber is situated in the component contact surface.

The sealing ring safeguards a good sealing between the electronic component and the vacuum chamber.

A yet further embodiment of the device according to the invention is characterized in that the device is provided with a displacement device for displacing the fastening mechanism with respect to the testing mechanism.

The displacement device is capable of displacing the fastening mechanism towards the testing mechanism after the electronic component has been correctly positioned on the fastening mechanism, whereupon an electronic contact is established between the electronic component under test and the testing mechanism.

The invention also has for its object to provide a method by which the disadvantages of the known method are unavoided.

This object is achieved in the method according to the invention in that the component contact surface is provided with a vacuum chamber connected to a vacuum means, and in that the electronic component is pulled against the component contact surface under vacuum by the vacuum means.

The fastening of the electronic component to the component contact surface by means of vacuum provides a secure connection between the electronic component and the fastening mechanism while at the same time compression forces exerted on the side of the electronic component facing away from the testing mechanism are avoided.

An embodiment of the method according to the invention is characterized in that the fastening mechanism together with the electronic component lying against it under vacuum is displaced relative to the testing mechanism by a displacement device such that an electronic contact is established between the testing mechanism and the electronic component.

An electronic contact between the electronic component and the testing mechanism is not achieved in this manner until after a correct positioning of the electronic component with respect to the fastening mechanism has been obtained. If the electronic contact with the testing mechanism is achieved immediately upon placement of the electronic component on the component contact surface, there will be a risk that the testing mechanism and/or the electronic component are/is damaged in the case of an incorrect positioning of the electronic component.

The invention will be explained in more detail below with reference to the drawing, in which:

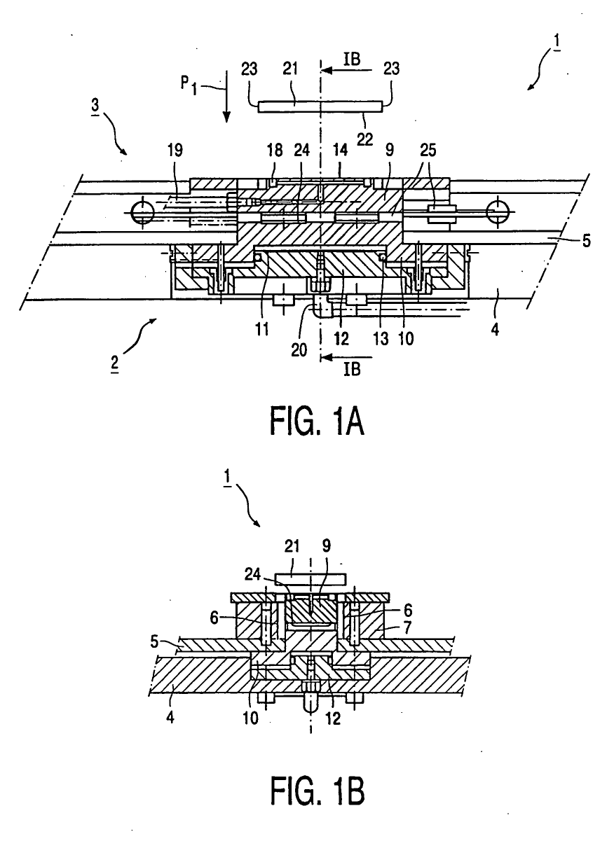

FIGS. 1A and 1B show a device according to the invention prior to the provision of an electronic component in lateral section and in cross-section, respectively,

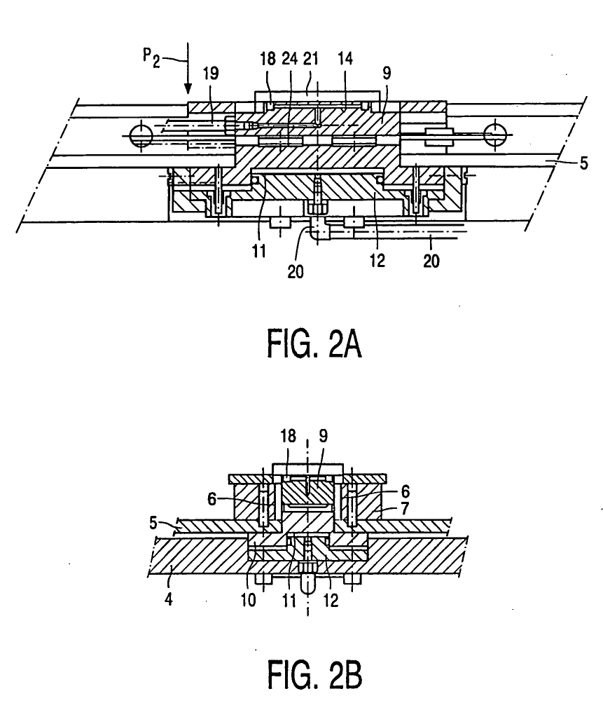

FIGS. 2A and 2B show the device of FIGS. 1A and 1B in lateral section and in cross-section, with the electronic component lying against a contact surface,

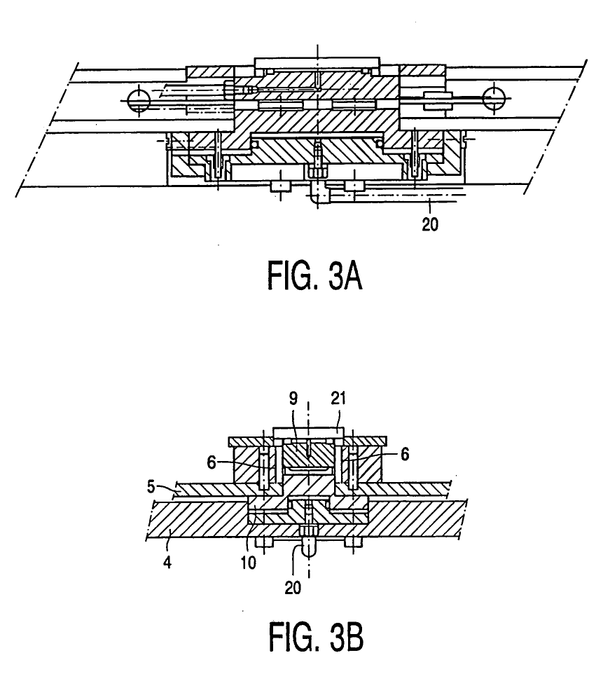

FIGS. 3A and 3B show the device of FIGS. 1A and 1B in lateral section and cross-section, with the electronic component in electrical contact with a testing mechanism,

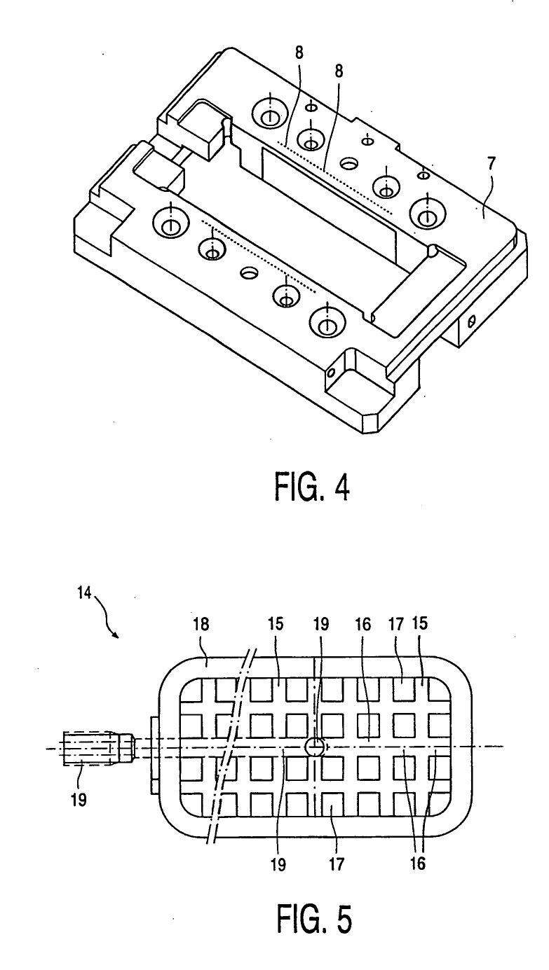

FIG. 4 is a perspective view of part of a testing mechanism of the device shown in FIGS. 1A and 1B, and

FIG. 5 is a plan view of the component contact surface of the fastening mechanism of the device shown in FIGS. 1A and 1B.

Corresponding components have been given the same reference numerals in the Figures.

FIGS. 1A and 1B are sectional views in two directions of a device 1 according to the invention which is provided with a testing mechanism 2 and a fastening mechanism 3. The testing mechanism 2 comprises a base plate 4 and an electronic test panel 5 situated thereon. The electronic test panel 5 is provided with test probes 6 extending transversely thereto and extending through openings 8 situated in a holder 7. The holder 7 is clearly shown in perspective view in FIG. 4.

The fastening mechanism 3 is provided with a metal block 9 which is provided at one side with L-shaped flanges 10 which define a chamber 11 situated therebetween. A portion 12 of the base plate 4 extends into the chamber 11, and a seal 13 is located between the L-shaped flanges 11 and said portion 12. The metal block 9 is provided at a side facing away from the chamber 11 with a component contact surface 14 which, as is visible in FIG. 5, comprises a number of channels 15, 16 extending transversely to one another and portions 17 situated between the channels 15, 16. The component contact surface 14 is provided with a silicone rubber sealing ring 18 adjacent its circumference. The channels 15, 16 form a vacuum chamber which is connected to a vacuum pump (not shown) via a vacuum line 19. The chamber 11 is also connected to a vacuum pump (not shown) via a vacuum line 20.

The number of test probes 6 and the spaces between the test probes 6 are adapted to the configuration of a component 21 to be tested by the device 1. In the holder 7 shown in FIG. 4, two rows of twenty openings 8 each are provided, through which a corresponding number of test probes 6 are passed. The component 21, for example an LCC (leadless chip carrier), comprises two rows of twenty contact points each which are situated at a side 22 of the component 21 facing the device 1.

The operation of the device 1 will be explained in more detail with reference to FIGS. 1A to 3B.

A component 21 is gripped at its sides 23 by a gripper mechanism (not shown) and is displaced in a direction indicated by arrow P1 until the component 21 has been moved from the position shown in FIGS. 1A, 1B to the position on the contact surface 14 shown in FIGS. 2A, 2B. The moment the component 21 is in a desired position with respect to the contact surface 14, a vacuum is generated in the channels 15, 16, which form the vacuum chamber, by a vacuum pump via the line 19, with the result that the component 21 is securely pulled against the component contact surface 14. The silicone rubber sealing ring 18 here provides a satisfactory sealing between the component contact surface 14 and the component 21. The electronic component 21 lies with its lower side 22 against the portions 17 of the component contact surface 14 then, such that a heat transmission takes place between the block 9 and the component 21. The block 9 is brought to a desired temperature by a heating element 24 and kept constant by means of a temperature sensor 25.

There is no contact yet between the test probes 6 and the electronic component 21 in the situation shown in FIGS. 2A, 2B.

To achieve this electronic contact, a vacuum is generated in the line 20 and in the chamber 11 by a vacuum pump, so that the block 9 and the component 21 sucked against it are displaced in the direction indicated by arrow P2 into the position shown in FIGS. 3A, 3B. In this position there is an electrical contact between the test probes 6 and the contact points (not visible) situated at the lower side 22 of the component 21. The electronic component 21 can now be tested in a desired manner by the testing mechanism 2. After the tests have been completed, the vacuum in the chamber 11 is lifted, whereupon the fastening mechanism 3 is displaced in a direction opposed to the arrow P2 away from the testing mechanism 2 under spring pressure owing to springs (not visible) located between the plate 12 and the L-shaped flanges 10. Subsequently or simultaneously, the vacuum in the channels 15, 16 forming the vacuum chamber is lifted, so that the electronic component 21 lies freely on the component contact surface 14. If the silicone rubber sealing ring 7 was slightly compressed during the generation of the vacuum in the chambers 15, 16, the lifting of the vacuum in the chambers 15, 16 will cause the silicone rubber sealing ring to return to its original shape, whereby the electronic component 21 will be slightly lifted off the portions 17. The electronic component 21 may then be removed from the device 1 by the gripper mechanism.

1. A device for testing an electronic component, which device is provided with a testing mechanism and a fastening mechanism which comprises a component contact surface at a side facing away from the testing mechanism, characterized in that the component contact surface is provided with a vacuum chamber connected to a vacuum means.

2. A device as claimed in claim 1, characterized in that the fastening mechanism is provided with a heating element by means of which the component contact surface can be heated.

3. A device as claimed in claim 2, characterized in that the component contact surface is provided with at least one heat transmission element.

4. A device as claimed in claim 3, characterized in that the vacuum chamber comprises channels which are provided in the component contact surface and which are in communication with one another, while the heat transmission element comprises portions of the component contact surface situated between the channels.

5. A device as claimed in claim 1, characterized in that a temperature sensor is located in the vacuum chamber.

6. A device as claimed in claim 1, characterized in that a sealing ring bounding the vacuum chamber is situated in the component contact surface.

7. A device as claimed in claim 1, characterized in that the device is provided with a displacement device for displacing the fastening mechanism with respect to the testing mechanism.

8. A method of testing an electronic component by means of a device, which device is provided with a testing mechanism and a fastening mechanism comprising a component contact surface at a side facing away from the testing mechanism, characterized in that the component contact surface is provided with a vacuum chamber connected to a vacuum means, such that the electronic component is pulled against the component contact surface under vacuum by the vacuum means.

9. A method as claimed in claim 8, characterized in that the fastening mechanism is provided with a heating element, and in that the electronic component is kept at a temperature desired for testing by means of the heating element.

10. A method as claimed in claim 8, characterized in that the fastening mechanism together with the electronic component lying against it under vacuum is displaced relative to the testing mechanism by means of a displacement device, such that an electronic contact is obtained between the testing mechanism and the electronic component.
